(19) United States
(12) Patent Application Publication
(10) Pub. No.: US 2007/0259192 A1
(43) Pub. Date: Nov. 8, 2007

(54) METHOD FOR PRODUCING COMPONENTS FOR ROCKET CONSTRUCTION

(75) Inventors: Josef GROEBER, Munich (DE); Gerhard TAUBENBERGER, Unterhaching (DE); Bernhard STAHN, Icking (DE)

Correspondence Address: GREENBLUM & BERNSTEIN, P.L.C., 1950 ROLAND CLARKE PLACE, RESTON, VA, 20191, US

(73) Assignee: EADS SPACE TRANSPORTATION GmBH, Bremen (DE)

(21) Appl. No.: 11/745,154

(22) Filed: May 7, 2007

(30) Foreign Application Priority Data
May 8, 2006 (DE) 102006021539.7-45

(51) Int. Cl. C23C 16/00; B32B 15/00

(52) U.S. Cl. 428/457; 205/191; 427/255.28

(57) ABSTRACT

Method for forming and component for rocket construction. Method includes depositing nickel on a base body by nickel vapor deposition to form a nickel coated base body. The nickel coated base body is processed to form the component.

### CROSS-REFERENCE TO RELATED APPLICATIONS

The present application claims priority under 35 U.S.C. §119 of German Application No. 10 2006 021 539.7-45, filed on May 8, 2006, the disclosure of which is expressly incorporated by reference herein in its entirety.

### BACKGROUND OF THE INVENTION

1. Field of the Invention

The invention relates to a method for producing components for rocket construction.

2. Discussion of Background Information

Various methods, e.g., electrodeposition of nickel, welding technologies or soldering methods are known for producing components for rocket construction, e.g., support structures for thrust chambers.

Typically, the use of ceramic components for thrust chambers has a disadvantage that the hollow bodies produced are not sufficiently gas-tight due to the type of design. However, this is not permissible in many fields of application. Thus, galvanic coatings and coatings containing silicon for sealing the surfaces are in the test phase.

Support structures for thrust chambers in rocket construction in particular are currently produced by electrodeposition of nickel, welding technologies, soldering methods or other methods. However, electrodeposition of nickel (e.g., at 0.01 to 0.02 mm/h) in particular has the disadvantage of very high throughput times in the production process.

At higher deposition rates (e.g., at approximately 0.25 mm/h), the Nickel Vapor Deposition (“NVD”) method shortens the throughput time considerably, thus reducing the overall development time.

In the NVD method, nickel tetracarbonyl gas is typically guided over a tempered master form in a special coating chamber and deposited as pure nickel on the surface of the master form in a chemical process. One of the main fields of application of the NVD method is the manufacture of nickel tools, e.g., nickel shells for kitchen sink tools. The NVD method is mainly used in die construction. For example, nickel is thereby deposited on a female mold in the NVD method. The nickel shell applied is separated from the female mold and used as a component. The production of a nickel shell by a female mold has the disadvantage that the production and application of a support structure on contoured, undercut base bodies (e.g., combustion chambers with nozzle expansion for rocket engines) is possible only through a splitting of the nickel shell for reasons of integration. This makes further process steps necessary in the subsequent integration to connect the individual nickel shells to one another and to the base body. This additional expenditure in production and the substantial risks to quality due to the necessary readjustment of the support structure have made this NVD method hitherto seem unsuitable for the production of rocket components.

For this reason the NVD method has not been used to manufacture components for rocket construction, e.g., support structures for thrust chambers, and consequently a use of the NVD method for this purpose is not currently known.

### SUMMARY OF THE INVENTION

Through its deposition characteristics, the NVD method can make it possible to seal the surface in small cavities. With continued deposition, an additional external support structure can be produced according to the operational load. Furthermore, the NVD method makes it possible to construct reinforcing, connecting and fastening elements such as, e.g., ribs, webs, flanges, weld studs, bolting surfaces, holders and bracket joints at the same time, or to produce them from an applied thick film by mechanical processing. In particular, in ceramic components with irregular surface structures and greatly fluctuating geometrical accuracy, a mechanical post-processing is thus no longer necessary before the metal connecting elements can be connected and/or sealed with a precision fit to the surface structure by interlocking elements or interlocked anchoring.

Connecting two components by screwing, welding, soldering and electroplating technology are generally known.

The NVD method additionally makes it possible to connect nickel components to components of other materials mechanically by undercutting, roughening or other anchor-formed shapings of the base body. For example, the mechanical connection of a milled metallic cool body to a load-bearing jacket can be produced in this manner.

Thus, the present invention provides a method for the production of components for rocket construction, which method can have a high deposition rate, and is able to apply nickel layers of uniform thickness onto base bodies of any shape in a manner conforming to the surface, and is able to remove nickel layers in open cavities.

In one embodiment, the present invention provides a method, including depositing nickel on a base body by nickel vapor deposition to form a nickel coated base body; and processing the nickel coated base body to form a component.

In another embodiment, the present invention provides a component for rocket construction.

In yet another embodiment, depositing of nickel can seal a porous ceramic base body and/or a non-ceramic fiber composite base body against gases and liquids.

In one embodiment, the component is a cooled base body of nickel comprising cavities for rocket drives.

In one embodiment, the cavities are formed by milling.

In another embodiment, the component produced is a non-cooled base body of nickel for rocket drives.

In yet another embodiment, the base body is composed of a milled metallic base structure.

In a further embodiment, the base body is composed of a ceramic fiber composite structure.

In one embodiment, the base body is composed of individual tubular elements.

In another embodiment the base body is composed of a milled metallic base structure.

In yet another embodiment, the base body is composed of a ceramic fiber composite structure.

In one embodiment, the processing comprises at least one of nickel vapor deposition, chemical processing, or mechanical processing.

In another embodiment, prior to the depositing of nickel on the base body, a chemical or electroplating pretreatment of the base body is performed.

In yet another embodiment, the electroplating pretreatment of the base body comprises electrolytic plating.

In a further embodiment, the nickel layer is at least 35 mm thick in at least one location.

In another embodiment, the cavities are filled with material.

In one embodiment, the present invention provides a product produced by the process including depositing nickel on a base body by nickel vapor deposition to form a nickel coated base body; and processing the nickel coated base body to form a component.

In one embodiment, the present invention provides a component for rocket construction including a base body having a nickel coating applied by nickel vapor deposition.

In another embodiment, the base body has open cooling channels.

In yet another embodiment, the base body has closed cooling channels.

Moreover, one property of the method according to the present invention is that, in contrast to the currently known methods, in the method according to the present invention, the base body together with the applied nickel layer can further be used as a component, and not only the applied nickel layer after having been previously separated from the base body. This can make it possible to use the NVD method for the production of components in rocket technology.

Other exemplary embodiments and advantages of the present invention may be ascertained by reviewing the present disclosure and the accompanying drawing.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 Depicts a left sectional view of a combustion chamber base body with open cooling channels in the connection area of the nickel layer; and
A right sectional view of a combustion chamber base body with closed cooling channels in the connection area of the nickel layer.

FIG. 2 Depicts a combustion chamber base body with cooling channels and filler, whereby 3 different embodiments for a positive connection of the nickel layer to the base body are shown:
Groove-shaped undercutting on both sides,
Microstructural surface design on the face surface of the cooling channel webs to anchor the nickel layer, and
Microstructural surface design on the lateral surfaces of the cooling channel webs to anchor the nickel layer.

FIG. 3 Depicts a base body of composite of individual round or rectangular tubes with applied support layer of nickel.

FIG. 4 Depicts a metallic or ceramic base structure with cooling channels and feed openings and a nickel layer applied on the outside and on the front, the final contour of which with ribs and webs is subsequently produced by mechanical processing. In addition, in the case of porous base structures, the NVD coating can form a seal against gases and liquids.

FIG. 5 Depicts a base body, support layer and distribution ring as integral component produced by NVD coating using suitable core materials to form and produce the cavities and subsequent mechanical processing of the outer contour.

FIG. 6 Depicts a zero-force positive connection without gaps of base bodies of different materials to a nickel layer to produce support structures and/or base material for the formation of connections and connection geometries or the production of integral articulations.

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

According to one embodiment of the present invention, and not intending to be limiting, the NVD method can be used for: (1) production of support structures on different metallic components, (2) production of combustion chamber base bodies with cooling channels of NVD nickel, (3) production of combustion chamber support structures and the necessary input and discharge distributors as an integral component for rocket drives and gas generators, (4) production of support structures on ceramic components, (5) coating of ceramic components for surface sealing, (6) production of connecting elements on metallic and ceramic base structures, (7) mechanical connection of base bodies to a nickel jacket, and (8) NVD deposition in combination with a soldered connection.

Exemplary advantages of the NVD method are, for example, high deposition rate, and application of nickel layers of uniform thickness to bodies of any shape in a manner conforming to the surface, and the removal in open cavities.

In one embodiment, the production of support structures on different metallic and non-metallic components pursuant to the method according to the invention is described below.

The base body to be coated can be positioned and prepared in the NVD chamber in the known manner. With the aid of the NVD method, a specific nickel layer is then applied, which is used as a support structure. The connection of the base body to the nickel layer is then further processed as a component.

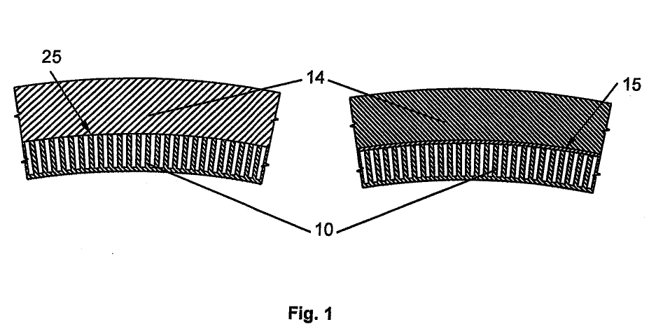

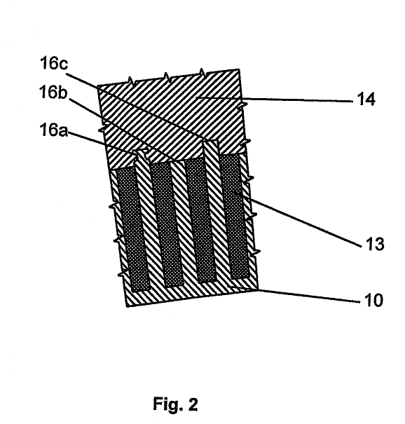

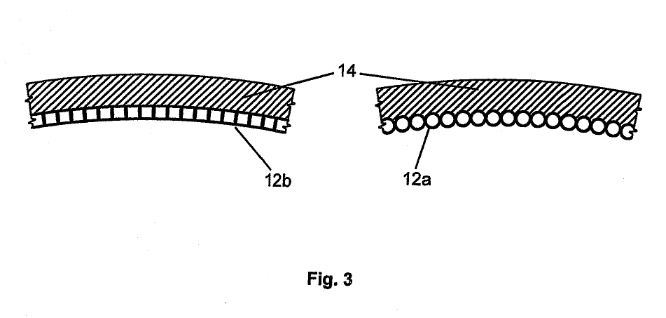

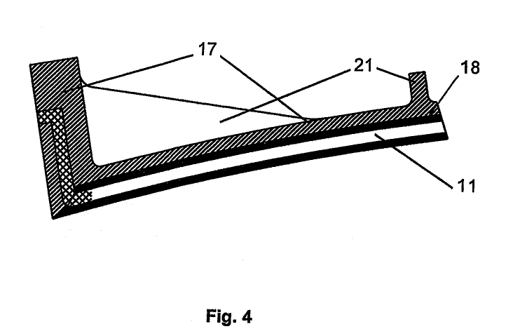

In two embodiments, the NVD coating can be used in rocket technology in the production of metallic and non-metallic cooled bodies that are very highly loaded thermally, and structurally. Examples are combustion chambers, expansion nozzles and cooled gas generators. The body to be coated can be composed, for example, of a (milled) metallic base structure (FIG. 1; 10) provided with cooling channels, a ceramic fiber composite structure (FIG. 4; 11), or of a composite of individual tubular elements (FIG. 3; 12a and 12b).

In one embodiment, the coating method can be carried out in different ways, for example with the cooling channels open or closed on the coating side, as shown for example in FIGS. 1 and 2, and as described below.

For example, in an embodiment, for cooling channels (25) open on the coating side, the cooling channels can be filled completely, or partially with a suitable material (13) and then coated with nickel (14) in the NVD method. In this coating method, a structure with molecular connection of the NVD layer (14) to the base structure (10) by suitable chemical or electroplating pretreatment of the surfaces to be coated can be achieved, but not required.

In another embodiment, the open cooling channels can be covered with a layer (15) before the coating by a different method, e.g., electroplating (15), and then coated in the NVD method. In this coating method, a structure with the molecular connection of the NVD layer (14) to the base structure (10) by suitable chemical or electroplating pretreatment of the surfaces to be coated can be achieved, but not required.

In yet another embodiment, the cooling channels can be processed mechanically or chemically (16a, 16b, 16c) on the surface to be coated such that a contoured geometry or engagement-like microstructures (16a) form that render possible an NVD cavity deposition. In this manner, a positive connection is ensured between a support structure and a base structure. The covering of the cooling channel before the coating can be carried out with a suitable filler (13).

In a further embodiment, a structure with the molecular connection of the NVD layer to the base structure by suitable chemical or electroplating pretreatment of the surfaces to be coated is contemplated.

Again, referring to FIGS. 1 and 2, NVD deposition in combination with a soldered connection pursuant to the method according to the invention is contemplated and described below.

The base body can be coated in the area of the bonding zone to the NVD nickel or a partial area thereof by electrodeposition with a suitable solder. Alternatively, the solder material can also be applied to the base body in the form of a foil. The NVD coating can then take place, and subsequently the soldering process is carried out in a soldering furnace. The described method has an advantage of precise form closure especially when large components are to be connected. Thus, a uniform soldering gap even with complex and undercut shaping of the bonding zone and with tolerance fluctuations from the production process of the individual parts can be provided.

As an example, in the case of combustion chambers, the base body (10) could be covered with solder in this manner at the bond surface (25) to the nickel jacket. Subsequently the cooling channels can be milled and filled with suitable material (13) before carrying out by way of an NVD coating, the application of the nickel jacket (14) without gaps. After the coating operation, the soldering process can be carried out between the base body and the NVD layer.

In another embodiment, the cooling channels (12a, 12b) can be closed on the coating side, see, e.g., FIG. 3. With such closed channels, structures with the molecular connection of the NVD layer to the base structure by suitable chemical or electroplating pretreatment of the surfaces can be coated.

In a further embodiment, it may be advantageous to form structures without a molecular connection of the NVD layer to the base structure to avoid thermal reactive forces with the influence of different temperatures. In addition, based on material or application, a separating layer of greater or lesser thickness by suitable pretreatment of the surfaces can be utilized.

In yet a further embodiment, the surfaces to be coated can be processed mechanically or chemically such that a geometry is formed that renders possible an NVD cavity deposition. Thus, a positive connection can be provided between the support structure and the base structure.

In another embodiment, when the surfaces to be coated are typically porous due to the material or manufacture, NVD cavity deposition can be advantageous in that a positive connection can be provided between the support structure and the base structure.

In another embodiment, the coating of ceramic components for surface sealing pursuant to the method according to the invention is shown for example in FIG. 4, and is described below.

Like the NVD coating of metallic materials, the nickel deposited in the NVD method can fill up the pores, such as formed in the production of ceramic components. Thus, the nickel coating can produce a seal from gases or liquids on the surface (18). Moreover, with thermally highly stressed components, the high ductility of the NVD nickel is thereby advantageous.

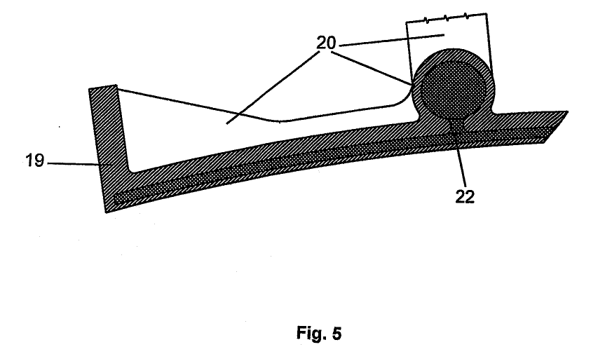

In a further embodiment, the production of combustion chamber base bodies from NVD nickel with integrated cooling channels pursuant to the method according to the invention is shown for example in FIG. 5, and described below.

A combustion chamber base body of 100% nickel is advantageous for certain engine types or when certain fuels are used. Thus, the NVD method is suitable for the production of a base structure (liner) provided with ribs as well as for the production of an integral overall body provided with cooling channels.

In an exemplary embodiment, a ribbed base structure can be produced through deposition of the NVD nickel on a female mold of corresponding shape, and wall thicknesses and finished contour of the ribbed base structure can be subsequently adapted and optimized by processing.

In another embodiment, the cavities (22) conducting coolant can be subsequently produced from suitable materials as dead cores and subsequently coated with NVD nickel (19). Wall thicknesses and the finished contour (20) of the base body can be subsequently adapted and optimized by processing. The cavities are formed by the core material being released after the coating operation with suitable auxiliaries.

In yet a further embodiment, the production of support structures on ceramic components pursuant to the method according to the invention is shown for example in FIG. 4, and is described below.

Similar to the coating of metallic materials, the NVD method can provide deposition on ceramic surfaces (11). The deposited nickel thereby penetrates into the porous surface (18), becomes anchored there and with continued coating forms the basis for the structural build-up (17).

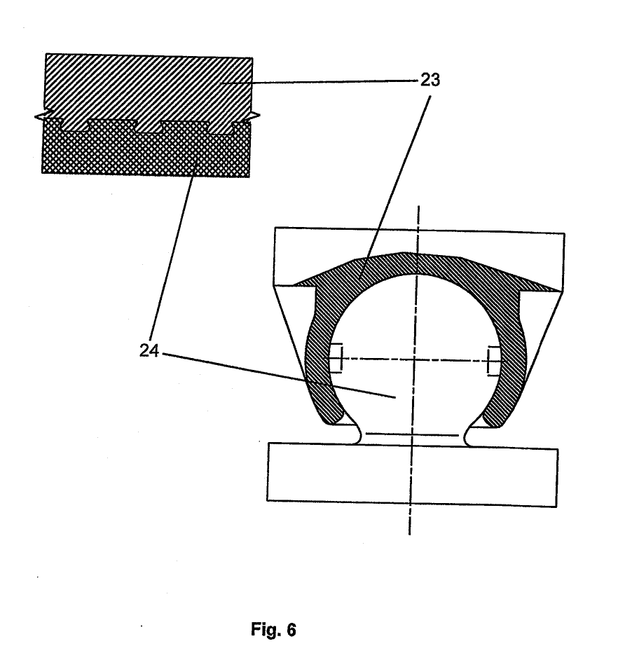

In yet another embodiment, the production of connecting elements on metallic and ceramic base structures pursuant to the method according the present invention is shown for example in FIGS. 5 and 6, and is described below.

In an embodiment, NVD having nickel layer thicknesses of more than 35 mm can currently be applied. These high layer thicknesses make it possible to build up connecting elements such as flanges (19), input and discharge distributors (20) and reinforcing rings (22) on the coated components directly or to produce them by subsequent mechanical processing of the NVD layer.

Further, the mechanical connection of base bodies and a nickel jacket pursuant to the method according to the invention is shown for example in FIG. 6, and described below.

The method described above for connecting cooling channel segments to a nickel jacket can be generally used to form mechanical connection(s) of base bodies and a nickel jacket. This method is of particular interest if nickel fittings (23) are to be connected to materials with different properties (24) and complex geometry without gaps. Examples would be nickel sandwich constructions with ceramics, fiber composite materials, and metals.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

Further, when an amount, concentration, or other value or parameter, is given as a list of upper preferable values and lower preferable values, this is to be understood as specifically disclosing all ranges formed from any pair of an upper preferred value and a lower preferred value, regardless whether ranges are separately disclosed.

What is claimed:

1. A method, comprising:
depositing nickel on a base body by nickel vapor deposition to form a nickel coated base body; and
processing the nickel coated base body to form a component.

2. The method according to claim 1,
wherein the component is a component for rocket construction.

3. The method according to claim 1, wherein the depositing of nickel seals a porous ceramic base body and/or a non-ceramic fiber composite base body against gases and liquids.

4. The method according to claim 2, wherein the component is a cooled base body of nickel comprising cavities for rocket drives.

5. The method according to claim 2, wherein the component produced is a non-cooled base body of nickel for rocket drives.

6. The method according to claim 1, wherein the base body is composed of a milled metallic base structure.

7. The method according to claim 3, wherein the base body is composed of a ceramic fiber composite structure.

8. The method according to claim 3, wherein the base body is composed of individual tubular elements.

9. The method according to claim 4, wherein the base body is composed of a milled metallic base structure.

10. The method according to claim 5, wherein the base body is composed of a ceramic fiber composite structure.

11. The method according to claim 1, wherein the processing comprises at least one of nickel vapor deposition, chemical processing, or mechanical processing.

12. The method according to claim 1, wherein, prior to the depositing of nickel on the base body, a chemical or electroplating pretreatment of the base body is performed.

13. The method according to claim 12, wherein the electroplating pretreatment of the base body comprises electrolytic plating.

14. The method according to claim 13, wherein the nickel layer is at least 35 mm thick in at least one location.

15. The method according to claim 4, wherein the cavities are formed by milling.

16. The method according to claim 4, wherein the cavities are filled with material.

17. A product produced by the process comprising:
depositing nickel on a base body by nickel vapor deposition to form a nickel coated base body; and
processing the nickel coated base body to form a component.

18. A component for rocket construction comprising:
a base body having a nickel coating applied by nickel vapor deposition.

19. The component according to claim 18, wherein the base body has open cooling channels.

20. The component according to claim 18, wherein the base body has closed cooling channels.
